(19) United States
(12) Patent Application Publication
(10) Pub. No.: US 2026/0239563 A1
(43) Pub. Date: Aug. 13, 2026

(54) DEVICE AND METHOD FOR COOLING ELECTRONIC COMPONENTS OF A COMPUTING SYSTEM

(71) Applicant: Quanta Computer Inc., Taoyuan City (TW)

(72) Inventors: Chao-Jung CHEN, Taoyuan City (TW); Yu-Nien HUANG, Taoyuan City (TW); Jen-Mao CHEN, Taoyuan City (TW); He-Chia LIN, Taoyuan City (TW)

(21) Appl. No.: 19/049,890

(22) Filed: Feb. 10, 2025

(51) Int. Cl. H05K 7/20

(52) U.S. Cl. CPC H05K 7/20263; H05K 7/20254; H05K 7/20727; H05K 7/20772

(57) ABSTRACT

A computing system and method include a heat exchanger and a liquid cooling unit for cooling an electronic component inside the computing system. The liquid cooling unit is designed to circulate a liquid coolant along a cooling path to remove heat generated by the electronic component. The heat exchanger is positioned adjacent the electronic component and opposite the liquid cooling unit. The heat exchanger is fluidly coupled to the liquid cooling unit that circulates the liquid coolant through the heat exchanger. The heat exchanger is designed to receive an air coolant and cools the air coolant using the liquid coolant. The air coolant then flows across the electronic component and removes heat generated thereby.

### FIELD OF THE INVENTION

The present invention relates generally to a computing system, and more specifically, to a device and method for cooling electronic components in a computing system.

### BACKGROUND OF THE INVENTION

As new technologies rapidly improve the efficiency and capability of computing systems, such as servers, thermal management has posed significant challenges. Servers of new generations generate enormous amounts of heat due to the operation of internal electronic components such as controllers, processors, and memory. Overheating from inefficient removal of such heat may cause damages to the components and shut down or impede the operation of the servers.

Due to the improvement of high-performance systems, the amount of heat that needs to be removed becomes higher with each new generation. For example, advances in artificial intelligence (AI) technology demand high memory power in servers. Such high memory power can drastically improve application response time especially as it relates to multitasking performance. High memory power is required for certain applications such as large database operations and video streaming. With the advent of even more powerful components, traditional air-cooling in combination with fan systems are inadequate to sufficiently remove heat generated by new generation servers.

Liquid cooling is highly efficient for rapid heat removal due to the superior thermal performance comparing with air-cooling. It is more effective in transporting heat away from a heat source than a radiator and allows heat removal from critical parts without noise pollution. Typically, a liquid cooling system includes a cold plate, which is a block that forms a network of internal channels for liquid coolant flow. Moreover, the cold plate is normally installed in contact with the electronic component. Circulating through the internal channels of the cold plate, the liquid coolant transfers generated heat away from the component.

In most servers, processors such as central processing units (CPUs) and graphical processing units (GPUs) are cooled by liquid cooling. Unlike CPUs and GPUs, memory banks are still cooled by air-cooling. Traditional air-cooling limits efficient heat dissipation. Such limitation is detrimental to increasing the capacity of memory banks, thus causing a bottleneck to the overall efficiency of the computing systems.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system includes an electronic component that generates heat during a computing operation. The electronic component has a first side and a second side. The second side is positioned opposite the first side. The computing system also includes a liquid cooling unit and a heat exchanger. The liquid cooling unit is positioned towards the first side of the electronic component and flows a liquid coolant towards the electronic component. The liquid coolant circulates along a cooling path to remove at least some of the heat generated by the electronic component. The heat exchanger is positioned towards the second side of the electronic component and fluidly coupled to the liquid cooling unit. Moreover, the heat exchanger is designed to receive an air coolant and cools the air coolant using the liquid coolant circulated by the liquid cooling unit. The air coolant then flows across the electronic component, in a direction from the second side to the first side.

According to one aspect of the present disclosure, the computing system includes a server, and the electronic component is included in the server.

According to another aspect of the present disclosure, the electronic component includes one or more processors and one or more memory banks. Moreover, the one or more memory banks include a DIMM (dual in-line memory module) bank.

According to a configuration of the above implementation, the one or more processors is selected from a group consisting of a central processing unit, a graphical processing unit, and any combination thereof.

According to another configuration of the above implementation, the cooling path is formed at least in part by a plurality of tubes.

According to a further configuration of the above implementation, the liquid coolant is selected from a group consisting of a mineral oil, a fluorinated liquid, a heat transfer fluid PG25, and any combination thereof.

According to a further aspect of the above implementation, the air coolant is ambient air that is directed to the electronic component after flowing through the heat exchanger.

According to a configuration of the above implementation, the ambient air is directed by a fan mounted inside a housing of the computing system.

According to yet another aspect of the present disclosure, a computing system includes a processing unit that generates heat during a computing operation. Additionally, the computing system includes a cold plate and a liquid cooling unit. The cold plate is coupled in thermal communication with the processing unit. The liquid cooling unit is fluidly coupled with the cold plate and circulates a liquid coolant along a cooling path to remove at least some of the heat generated by the processing unit. Moreover, the computing system includes one or more memory banks and a heat exchanger. The one or more memory banks generate heat during the computing operation and are positioned adjacent the processing unit. The heat exchanger is coupled in fluid communication with the liquid cooling unit that circulates the liquid coolant through the heat exchanger. Additionally, the heat exchanger is disposed in such a way that the processing unit is positioned between the heat exchanger and the liquid cooling unit. Further, the heat exchanger is positioned adjacent the one or more memory banks. The heat exchanger is designed to receive an airflow and cools the airflow by the liquid coolant. The airflow is then directed to flow through the one or more memory banks to remove heat generated by the one or more memory banks.

According to a configuration of the above implementation, the processing unit is selected from a group consisting of a central processing unit (CPU), a graphical process unit (GPU), and any combination thereof.

According to another configuration of the above implementation, the one or more memory banks is a DIMM (dual in-line memory module) bank.

According to yet another configuration of the above implementation, the one or more of the computing devices is a server.

According to a further configuration of the above implementation, the computing system include a plurality of tubes that is configured to fluidly couple the heat exchanger to the liquid cooling unit.

According to yet another aspect of the above implementation, the liquid coolant is selected from a group consisting of a mineral oil, a fluorinated liquid, a heat transfer fluid PG25, and any combination thereof.

According to a further aspect of the above implementation, the airflow is directed by a fan mounted inside a housing of the computing system.

According to yet another aspect of the present disclosure, a method is provided for cooling an electronic component of a computing system during a computing operation. The method includes mounting a heat exchanger inside the computing system. The heat exchanger is positioned adjacent a second side of the electronic component that also has a first side opposite the second side. The method fluidly couples the heat exchanger to a liquid cooling unit that is positioned towards the first side. The liquid cooling unit then flows a liquid coolant towards the electronic component to remove heat generated by the electronic component. Moreover, the heat receives and cools an air coolant. Further, the air coolant flows in a direction from the second side to the first side to remove the heat generated by the electronic component.

According to a configuration of the above implementation, the method further includes mounting a fan inside the computing system and adjacent the heat exchanger. In this configuration, the heat exchanger is designed to be positioned between the fan and the second side of the electronic component. Additionally, the fan directs the air coolant to the heat exchanger and is cooled by the coolant circulating within the heat exchanger.

According to another configuration of the above implementation, the method further includes mounting a cold plate on the electronic component. The cold plate is designed to be in thermal communication with the electronic component. Moreover, the cold plate is fluidly coupled with the liquid cooling unit. The liquid cooling unit flows the liquid coolant within the cold plate to remove heat from the electronic component.

According to yet another configuration of the above implementation of the method, the electronic component is included in a server.

According to a further configuration of the above implementation of the method, the electronic component includes one or more processors and one or more memory banks. Moreover, the one or more memory banks is a DIMM (dual in-line memory module) bank.

According to yet a further configuration of the above implementation of the method, the liquid coolant is selected from a group consisting of a mineral oil, a fluorinated liquid, a heat transfer fluid PG25, and any combination thereof.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a top view showing a computing system with a liquid cooling unit and a heat exchanger configured to cool electronic components inside the computing system, according to certain aspects of the present disclosure.

FIG. 1P is top view showing a prior computing system with a liquid cooling unit configured to cool electronic components inside the computing system, according to certain aspects of the present disclosure.

FIG. 2 is a flowchart diagram showing a method for cooling electronic components in a computing system by use of a heat exchanger coupled with a liquid cooling unit, according to certain aspects of the present disclosure.

FIG. 3 is a flowchart diagram showing an alternative method for cooling the electronic components in the computing system using a fan installed adjacent the heat exchanger, according to certain aspects of the present disclosure.

FIG. 4 is a flowchart diagram showing another alternative for cooling the electronic components in the computing system using a cold plate coupled with the electronic components and the liquid cooling unit, according to certain aspects of the present disclosure.

### DETAILED DESCRIPTION

A computing system and a method are designed to provide efficient cooling of heat-generating electronic components such as memory banks, central processing units (CPUs), and graphical processing units (GPUs). The computing system and method take advantage of liquid cooling technology and integrate both liquid cooling and air cooling. The integrated cooling allows significant capacity increase of these electronic components without overheat risks.

The computing system includes a heat exchanger and a liquid cooling unit. The liquid cooling unit is fluidly coupled with a cold plate. The cold plate is mounted to an electronic component inside the computing system. The cold plate is designed to be in thermal communication with the electronic component. During a computing operation of the computing system, the liquid cooling unit circulates a liquid coolant through the cold plate to remove heat generated by the electronic component. For example, a central processing unit (CPU) in the computing system has a cold plate. Through the cold plate, the liquid coolant removes a significant portion of the heat generated during the computing operation.

The heat exchanger is mounted inside the computing system adjacent the electronic component. The heat exchanger is positioned opposite the liquid cooling unit across the electronic component. Fluidly coupled with the liquid cooling unit, the heat exchanger receives an air coolant and cools the air coolant by the circulating liquid coolant from the liquid cooling unit. The air coolant is either ambient air or an airflow generated by a fan inside the computing system. The air coolant then flows through the electronic component to remove, at least partially, the heat generated by the electronic component during the computing operation.

In a computing system that has multiple electronic components, the heat exchanger is designed to effectively remove heat generated by electronic components that do not have cold plates attached. For example, one or more memory banks in the computing system do not have cold plates. As the air coolant, cooled by the heat exchanger, flows through the one or more memory banks, the air coolant removes heat generated by the one or more memory banks. The air coolant has lower temperature that that in a prior computing system that does not have such a heat exchanger. Thus, the air cooling of the one or more memory banks is significantly more efficient in the system than in the prior system. Accordingly, comparing with the prior computing system, the computing system reduces overheat risks and allows substantial capacity increase of the one or more memory banks.

The method is designed to integrate the heat exchanger with the liquid cooling unit to effectively cool an electronic component in the computing system during the computing operation. Specifically, the method starts with mounting the heat exchanger inside the computing system. The electronic component has a first side and a second side. The heat exchanger is positioned adjacent the second side of the electronic component and opposite the first side. The method fluidly couples the heat exchanger to the liquid cooling unit with the liquid cooling unit positioned towards the first side of the electronic component. Then, the method flows the liquid coolant, via the liquid cooling unit, towards the electronic component to remove heat generated by the electronic component. The method cools the air coolant received by the heat exchanger. The air coolant flows in a direction from the second side to the first side to remove the heat generated by the electronic component. Thus, the method provides optimized cooling to critical electronic components, allowing desired capacity increases while reducing overheat risks.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

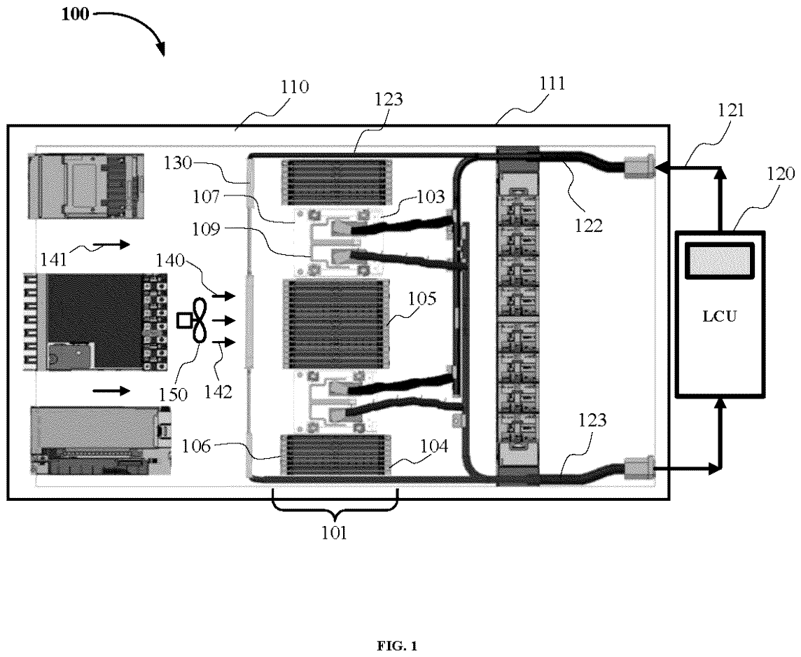

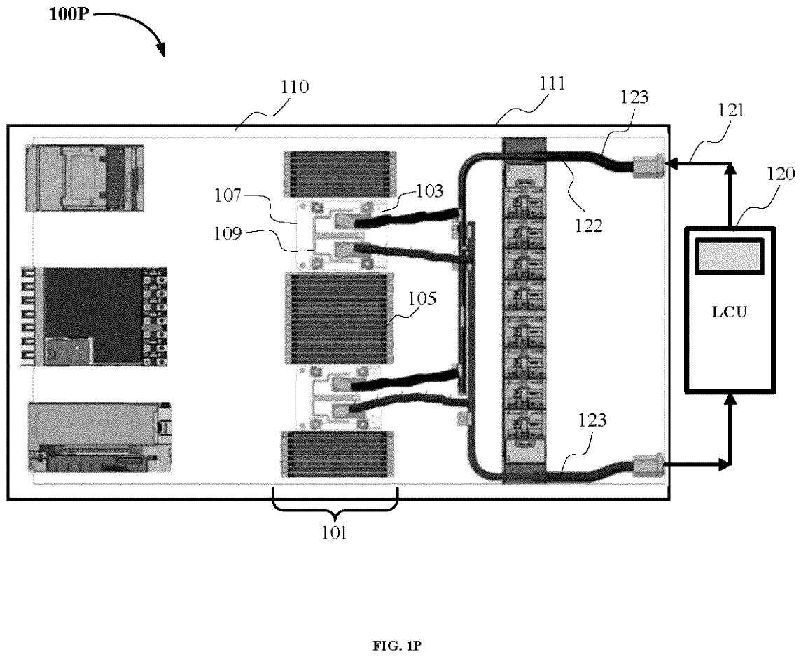

FIG. 1 illustrates a computing system 100 with a liquid cooling unit and a heat exchanger configured to cool electronic components inside the computing system 100. Typically, the computing system is a server 110 and has a housing 111. The computing system 100 includes an electronic component 101 that generates heat during a computing operation. For example, in the computing system 100, the electronic component 101 includes one or more processors 103, and/or one or more memory banks 105. The one or more processors 103 include a central processing unit (CPU), a graphical processing unit (GPU), and any combination of one or more CPUs and one or more GPUs. The one or more memory banks 105 include a DIMM (dual in-line memory module) bank.

In some implementations, the electronic component 101 includes a power supply, a power management integrated circuit (IC), a baseboard management controller (BMC), a storage device, a fan module, a non-volatile memory device, or any other component. Moreover, the electronic component 101 is included in the server 110. Further, the electronic component 101 has a first side 104 and a second side 106. The second side 106 is positioned opposite the first side 104.

The computing system 100 includes a liquid cooling unit 120, as shown in FIG. 1. In some implementations, the liquid cooling unit 120 includes a cooling distribution unit. The liquid cooling unit 120 is positioned towards the first side 104 of the electronic component 101. For example, the liquid cooling unit 120 is positioned outside the housing 111 of the computing system 100. Moreover, the liquid cooling unit 120 is designed to cause a liquid coolant 121 to flow towards the electronic component 101. Further, the liquid coolant 121 circulates along a cooling path 122 to remove at least some of the heat generated by the electronic component 101.

In some implementations, the liquid coolant 121 is selected from a group consisting of a mineral oil, a fluorinated liquid, a heat transfer fluid PG25, and any combination of the suitable fluids. Moreover, the cooling path 122 is formed at least in part by a plurality of tubes 123.

As shown in FIG. 1, the computing system 100 includes a processing unit 107 that has a cold plate 109. The one or more memory banks 105 are positioned adjacent the processing unit 107. The processing unit 107, for example, includes a central processing unit (CPU), a graphical processing unit (GPU), and any combination of one or more CPUs and one or more GPUs. In some implementations, the processing unit 107 is the same, or substantially similar to, the one or more processors 103. The cold plate 109 is made of any suitable material such as metals or thermally conductive materials. The cold plate 109 is coupled in thermal communication with the processing unit 107. Moreover, the cold plate 109 is fluidly coupled with the liquid cooling unit 120 via the plurality of tubes 123. The liquid cooling unit 120 circulates the liquid coolant 121, via the cooling path 122, through the cold plate 109. Thus, the liquid coolant 121 removes, at least partially, heat generated by the processing unit 107 through the cold plate 109.

The computing system 100 includes a heat exchanger 130, as shown in FIG. 1. The heat exchanger 130 is coupled in fluid communication with the liquid cooling unit 120. For example, the heat exchanger 130 is fluidly coupled to the liquid cooling unit 120 through the plurality of tubes 123. Specifically, the heat exchanger 130 is configured in such a way that the processing unit 107 is positioned between the heat exchanger 130 and the liquid cooling unit 120. Moreover, the heat exchanger 130 is positioned adjacent the one or more memory banks 105. Further, the heat exchanger 130 is designed to receive an airflow 142. The heat exchanger 130 cools the airflow 142 by the liquid coolant 121. Then, the airflow 142 is directed to the one or more memory banks 105, flows through and removes heat from the one or more memory banks 105. The heat exchanger 130 includes shell-and-tube heat exchangers, double-pipe heat exchangers, plate heat exchangers, plate-and-shell heat exchangers, plate fin heat exchangers, finned tube heat exchangers, and any other suitable heat exchangers.

In some implementations, a fan 150 is mounted inside the computing system 100, as shown in FIG. 1. The fan 150 is positioned adjacent the heat exchanger 130 and configured to direct the airflow 142 to the one or more memory banks 105. Since the processing unit 107 is positioned adjacent to the one or more memory banks 105, the airflow 142 also provides cooling to the processing unit 107. In some implementations, the airflow 142 is ambient air 141 that is cooled by the heat exchanger 130. This air cooling of the processing unit 107, by the airflow 142, is additional to the liquid cooling by the cold plate 109 through the liquid coolant 121. Thus, the computing system 100 achieves substantial cooling efficiency by integrating the heat exchanger 130 and the liquid cooling unit 120. This cooling efficiency improves the thermal performance of the processing unit 107 and the one or more memory banks 105. Accordingly, the computing system 100 allows significant capacity increases of the critical components including the processing unit 107 and the one or more memory banks 105 without overheat risks.

FIG. 1P shows a prior computing system 100P with a liquid cooling unit configured to cool electronic components inside the computing system 100P. Similar to the computing system 100 in FIG. 1, the prior art computing system 100P has the liquid cooling unit 120 that circulates the liquid coolant 121 through the electronic component 101. The electronic component 101 includes the one or more processors 103 and the processing unit 107 coupled in thermal communication with the cold plate 109. Additionally, the electronic component 101 includes the one or more memory banks 105. The liquid cooling unit 120 is fluidly coupled with the cold plate 109 through the plurality of tubes 123. The prior art computing system 100P includes the server 110 that has the housing 111. The prior art computing system 100P, however, does not have the heat exchange 130 as shown in FIG. 1.

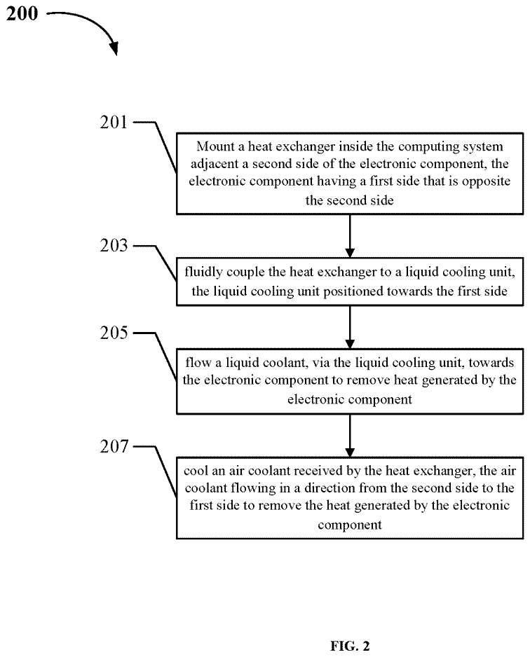

FIG. 2 shows a method 200 for cooling an electronic component in a computing system by use of a heat exchanger coupled with a liquid cooling unit. Specifically, the method 200 includes mounting the heat exchanger inside the computing system adjacent a second side of the electronic component (Step 201). The electronic component has a first side that is opposite the second side. Additionally, the method includes fluidly coupling the heat exchanger to the liquid cooling unit (Step 203). The liquid cooling unit is positioned towards the first side. The method also includes flowing a liquid coolant, via the liquid cooling unit, towards the electronic component to remove heat generated by the electronic component (Step 205). Further, the method includes cooling an air coolant received by the heat exchanger (Step 207). In this step, the air coolant flows in a direction from the second side to the first side to remove the heat generated by the electronic component.

In Step 201 and Step 203 of the method 200, the heat exchanger is mounted inside the computing system. The heat exchanger is positioned in such a way that the electronic element is positioned between the heat exchanger and the liquid cooling system. The electronic component includes one or more processing unit such as a central processing unit (CPU), a graphical processing unit (GPU), one or more memory banks such as DIMM (dual in-line memory module) banks, and any combination of the CPUs, GPUs, and/or memory banks. In some implementations, the electronic component is included in a server. Moreover, the heat exchanger includes shell-and-tube heat exchangers, double-pipe heat exchangers, plate heat exchangers, plate-and-shell heat exchangers, plate fin heat exchangers, finned tube heat exchangers, and any other suitable heat exchangers. Further, the liquid coolant is selected from a group consisting of a mineral oil, a fluorinated liquid, a heat transfer fluid PG25, and any combination of suitable liquids.

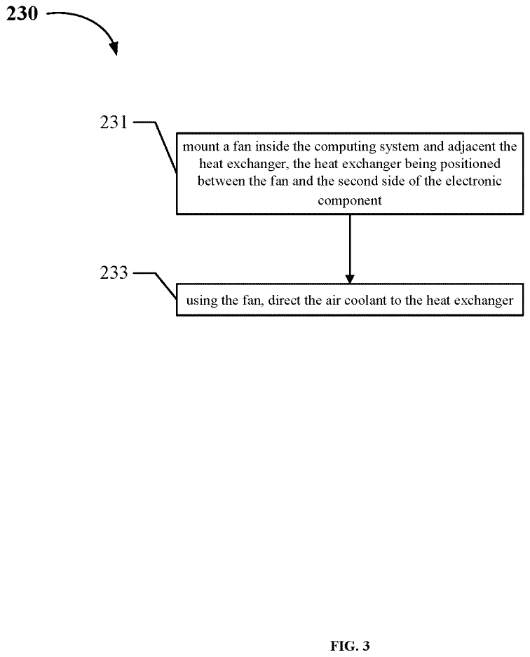

FIG. 3 shows an alternative method 230 for cooling the electronic component in the computing system using a fan installed adjacent the heat exchanger. Specifically, the method 230 includes mounting a fan inside the computing system and adjacent the heat exchanger (Step 231). The heat exchanger is positioned between the fan and the second side of the electronic component. Then, using the fan, the method 230 directs the air coolant to the heat exchanger (Step 233). With the liquid coolant circulated inside, the heat exchanger cools the air coolant. Subsequently, the air coolant is directed to the electronic component and removes the heat generated by the electronic component.

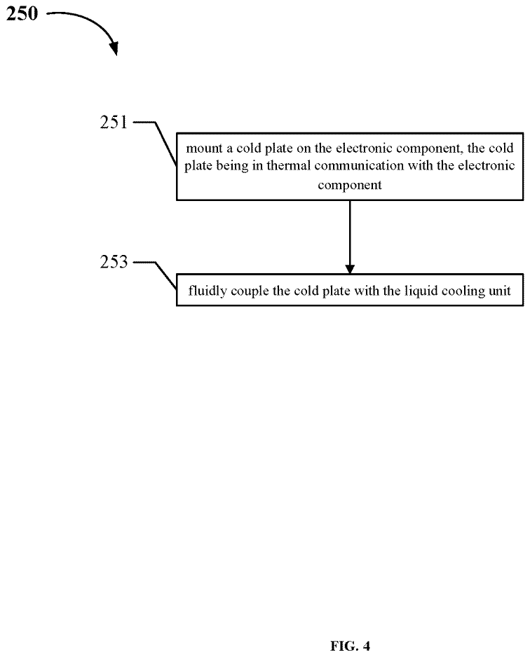

FIG. 4 shows another alternative method 250 for cooling the electronic component in the computing system using a cold plate coupled with the electronic component and the liquid cooling unit. Specifically, the method 250 includes mounting a cold plate on the electronic component (Step 251). The cold plate is in thermal communication with the electronic component. Additionally, the method 250 includes fluidly coupling the cold plate with the liquid cooling unit (Step 253). In this method 250, the electronic component, e.g., a central processing unit (CPU) or a graphical processing unit (GPU), is cooled by the liquid cooling unit via a thermally coupled cold plate. The cold plate is made of any suitable material such as metals or thermally conductive materials.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

What is claimed is:

1. A computing system comprising:
an electronic component that generates heat during a computing operation, the electronic component having a first side and a second side, the second side being opposite the first side;
a liquid cooling unit positioned towards the first side, the liquid cooling unit causing a liquid coolant to flow towards the electronic component, the liquid coolant circulating along a cooling path to remove at least some of the heat generated by the electronic component; and
a heat exchanger coupled to the liquid cooling unit and positioned towards the second side, the heat exchanger receiving an air coolant, the heat exchanger, using the liquid coolant, cooling the air coolant that flows in a direction from the second side to the first side.

2. The computing system of claim 1, wherein the electronic component is included in a server.

3. The computing system of claim 1, wherein the electronic component includes one or more processors and one or more memory banks, the one or more memory banks being a DIMM (dual in-line memory module) bank.

4. The computing system of claim 3, wherein the one or more processors is selected from a group consisting of a central processing unit, a graphical processing unit, and any combination thereof.

5. The computing system of claim 1, wherein the cooling path is formed at least in part by a plurality of tubes.

6. The computing system of claim 1, wherein the liquid coolant is selected from a group consisting of a mineral oil, a fluorinated liquid, a heat transfer fluid PG25, and any combination thereof.

7. The computing system of claim 1, wherein the air coolant is ambient air that is directed to the electronic component after flowing through the heat exchanger.

8. The computing system of claim 7, wherein the ambient air is directed by a fan mounted inside a housing of the computing system.

9. A computing system comprising:
a processing unit that generates heat during a computing operation;
a cold plate coupled in thermal communication with the processing unit;
a liquid cooling unit fluidly coupled with the cold plate, the liquid cooling unit circulating a liquid coolant along a cooling path to remove at least some of the heat generated by the processing unit;
one or more memory banks generating heat during the computing operation, the one or more memory banks positioned adjacent the processing unit; and
a heat exchanger coupled in fluid communication with the liquid cooling unit, the processing unit being positioned between the heat exchanger and the liquid cooling unit, the heat exchanger positioned adjacent the one or more memory banks, the heat exchanger receiving an airflow, the heat exchanger cooling the airflow by the liquid coolant, and the airflow being directed to the one or more memory banks.

10. The computing system of claim 9, wherein the processing unit is selected from a group consisting of a central processing unit (CPU), a graphical process unit (GPU), and any combination thereof.

11. The computing system of claim 9, wherein the one or more memory banks is a DIMM (dual in-line memory module) bank.

12. The computing system of claim 9, further comprising a plurality of tubes that is configured to fluidly couple the heat exchanger to the liquid cooling unit.

13. The computing system of claim 9, wherein the liquid coolant is selected from a group consisting of a mineral oil, a fluorinated liquid, a heat transfer fluid PG25, and any combination thereof.

14. The computing system of claim 9, wherein the airflow is directed by a fan mounted inside a housing of the computing system.

15. A method of cooling an electronic component of a computing system during a computing operation, the method comprising:
mounting a heat exchanger inside the computing system adjacent a second side of the electronic component, the electronic component having a first side that is opposite the second side;
fluidly coupling the heat exchanger to a liquid cooling unit, the liquid cooling unit positioned towards the first side;
flowing a liquid coolant, via the liquid cooling unit, towards the electronic component to remove heat generated by the electronic component; and
cooling an air coolant received by the heat exchanger, the air coolant flowing in a direction from the second side to the first side to remove the heat generated by the electronic component.

16. The method of claim 15, further comprising:
mounting a fan inside the computing system and adjacent the heat exchanger, the heat exchanger being positioned between the fan and the second side of the electronic component; and
using the fan, directing the air coolant to the heat exchanger.

17. The method of claim 15, further comprising:
mounting a cold plate on the electronic component, the cold plate being in thermal communication with the electronic component; and
fluidly coupling the cold plate with the liquid cooling unit.

18. The method of claim 15, wherein the electronic component is included in a server.

19. The method of claim 15, wherein the electronic component includes one or more processors and one or more memory banks, the one or more memory banks being a DIMM (dual in-line memory module) bank.

20. The method of claim 15, wherein the liquid coolant is selected from a group consisting of a mineral oil, a fluorinated liquid, a heat transfer fluid PG25, and any combination thereof.
